(19) United States
(12) Patent Application Publication
(10) Pub. No.: US 2025/0105188 A1
(43) Pub. Date: Mar. 27, 2025

(54) PACKAGE STRUCTURE

(71) Applicant: Advanced Semiconductor Engineering, Inc., Kaohsiung (TW)

(72) Inventors: Paofa WANG, Kaohsiung (TW); Huang Ming CHANG, Kaohsiung (TW); Yung-Hsing CHANG, Kaohsiung (TW); Yung-Chi CHEN, Kaohsiung (TW); Hsiu-Hung SU, Kaohsiung (TW)

(73) Assignee: Advanced Semiconductor Engineering, Inc., Kaohsiung (TW)

(21) Appl. No.: 18/371,377

(22) Filed: Sep. 21, 2023

(51) Int. Cl. H01L 23/00; H01L 23/498

(52) U.S. Cl. CPC H01L 24/13; H01L 24/16; H01L 24/73; H01L 23/49816; H01L 23/49822; H01L 24/32; H01L 24/48; H01L 2224/13019; H01L 2224/1319; H01L 2224/13499; H01L 2224/16225; H01L 2224/32225; H01L 2224/48105; H01L 2224/48227; H01L 2224/73253; H01L 2924/16235; H01L 2924/1815

(57) ABSTRACT

A package structure is provided. The package structure includes a substrate, a sensing device, a light transmissive member, and a bonding structure. The sensing device is over the substrate, and the light transmissive member is over the sensing device. The bonding structure has an upper surface connected to the light transmissive member and a lower surface connected to the sensing device. A width of the upper surface is less than a width of the lower surface of the bonding structure.

### BACKGROUND

### 1. Technical Field

The present disclosure relates generally to a package structure.

### 2. Description of the Related Art

In an image sensor package, a light transmissive plate may be connected to a sensing device through a bonding layer. When the bonding layer does not have a sufficient structural strength, the entire package structure may be easily damaged during manufacture.

### SUMMARY

In one or more arrangements, a package structure includes a substrate, a sensing device, a light transmissive member, and a bonding structure. The sensing device is over the substrate, and the light transmissive member is over the sensing device. The bonding structure has an upper surface connected to the light transmissive member and a lower surface connected to the sensing device. A width of the upper surface is less than a width of the lower surface of the bonding structure.

In one or more arrangements, a package structure includes a substrate, a sensing device, a light transmissive member, and a bonding structure. The sensing device is over the substrate, and the light transmissive member is over the sensing device. The bonding structure has an upper surface contacting the light transmissive member, a lower surface contacting the sensing device, and a lateral surface including a first concave portion recessed toward an edge portion of the upper surface or an edge portion of the lower surface of the bonding structure.

In one or more arrangements, a package structure includes a substrate, a sensing device, a light transmissive member, and a bonding structure. The sensing device is over the substrate, and the light transmissive member is over the sensing device. The bonding structure is connected to the light transmissive member and the sensing device. The sensing device, the light transmissive member, and the bonding structure collectively define a cavity space, and a width of a top surface of the cavity space is greater than a width of a bottom surface of the cavity space.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a top view of a portion of a package structure in accordance with some arrangements of the present disclosure.

FIG. 2A is a cross-section of a portion of a package structure in accordance with some arrangements of the present disclosure.

FIG. 2B is a cross-section of a portion of a package structure in accordance with some arrangements of the present disclosure.

FIG. 2C is a cross-section of a portion of a package structure in accordance with some arrangements of the present disclosure.

FIG. 2D is a cross-section of a portion of a package structure in accordance with some arrangements of the present disclosure.

FIG. 2E is a cross-section of a portion of a package structure in accordance with some arrangements of the present disclosure.

FIG. 3 is a cross-section of a package structure in accordance with some arrangements of the present disclosure.

FIG. 4A is a cross-section of a portion of a package structure in accordance with some arrangements of the present disclosure.

FIG. 4B is a cross-section of a portion of a package structure in accordance with some arrangements of the present disclosure.

FIG. 4C is a cross-section of a portion of a package structure in accordance with some arrangements of the present disclosure.

FIG. 4D is a cross-section of a portion of a package structure in accordance with some arrangements of the present disclosure.

FIG. 5A, FIG. 5B, FIG. 6A, FIG. 6B, FIG. 7, and FIG. 8 illustrate various stages of an exemplary method for manufacturing a package structure in accordance with some arrangements of the present disclosure.

Common reference numerals are used throughout the drawings and the detailed description to indicate the same or similar elements.

### DETAILED DESCRIPTION

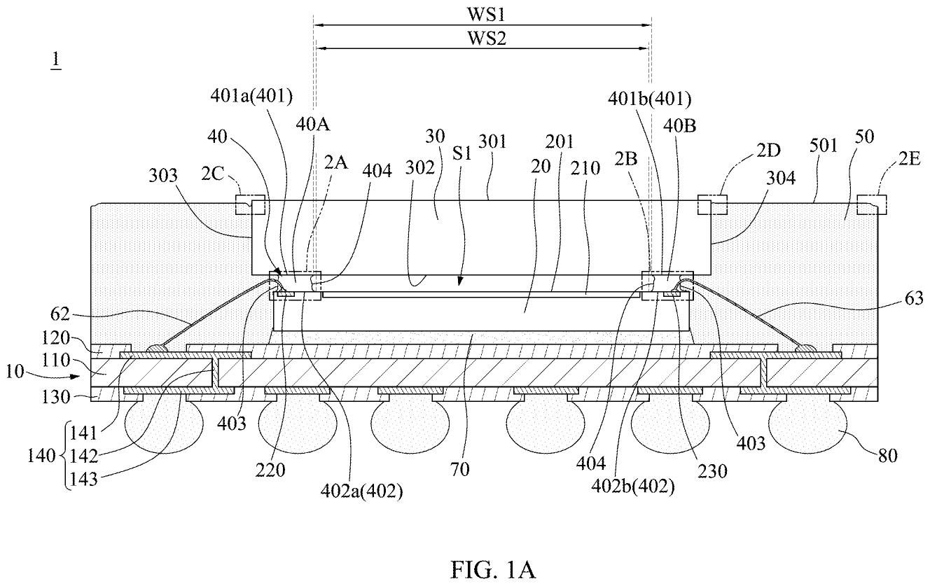

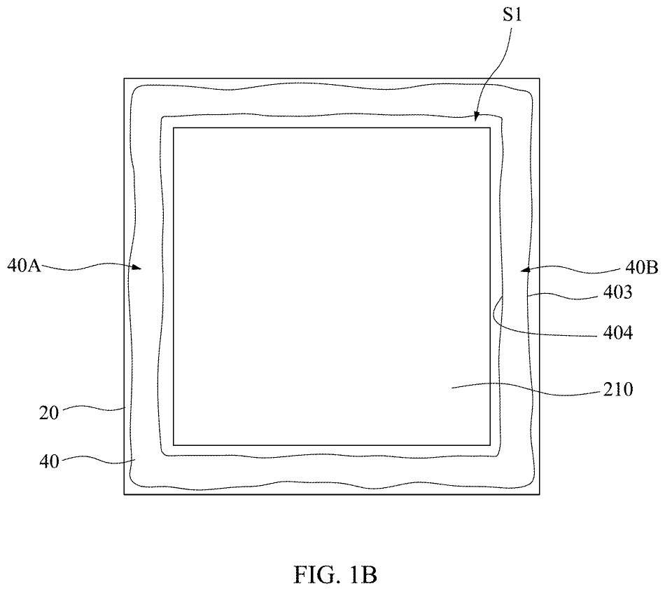

FIG. 1A is a cross-section of a package structure 1 in accordance with some arrangements of the present disclosure. FIG. 1B is a top view of a portion of a package structure 1 in accordance with some arrangements of the present disclosure. The package structure 1 may include a substrate 10, a sensing device 20, a light transmissive member 30, a bonding structure 40, an encapsulant 50, conductive wires 62 and 63, an adhesive layer 70, and electrical contacts 80. In some arrangements, FIG. 1B is a top view of the sensing device 20 and the bonding structure 40. The package structure 1 may be referred to as an image molding ball grid array (iMBGA) package.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, which may include such as a plurality of conductive traces and/or a plurality of conductive vias. The interconnection structure may include a redistribution layer (RDL) and/or a grounding element. In some arrangements, the substrate 10 may include an organic substrate or a leadframe. In some arrangements, the substrate 10 may include a ceramic material or a metal plate. In some arrangements, the substrate 10 may include a two-layer substrate which includes a core layer and a conductive material and/or structure disposed on an upper surface and a bottom surface of the substrate. The substrate 10 may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The substrate 10 may include one or more conductive elements, surfaces, contacts, or pads. In some arrangements, the substrate 10 includes a core layer 110, dielectric layers 120 and 130, and a conductive structure 140 (also referred to as “a redistribution layer (RDL)”). In some arrangements, the conductive structure 140 includes conductive layers 141, 142, and 143. The conductive layers 141 and 143 may be or include conductive patterns or conductive pads, and the conductive layers 143 may be or include conductive vias or conductive pillars. In some arrangements, the conductive layers 141, 142, and 143 may independently include a conductive material such as a metal or metal alloy. Examples include gold (Au), silver (Ag), aluminum (Al), copper (Cu), or an alloy thereof. The core layer 110 and the dielectric layers 120 and 130 may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

The sensing device 20 may be disposed over the substrate 10. In some arrangements, the sensing device 20 is adhered to the substrate 10 through the adhesive layer 70. The adhesive layer 70 may be or include a die attach film (DAF). In some arrangements, the sensing device 20 includes a sensing area 210 and conductive pads 220 and 230 exposed by an upper surface 201 of the sensing device 20. In some arrangements, the sensing device 20 is electrically connected to the substrate 10 (e.g., the conductive structure 140) through the conductive wires 62 and 63. In some arrangements, the conductive wire 62 electrically connects the conductive pad 220 to the conductive layer 141 of the substrate 10. In some arrangements, the conductive wire 63 electrically connects the conductive pad 230 to the conductive layer 141 of the substrate 10. The sensing device 20 may be or include an image sensor chip.

The light transmissive member 30 may be disposed over the sensing device 20. The light transmissive member 30 has an upper surface 301, a lower surface 302, and lateral surfaces 303 and 304. In some arrangements, the light transmissive member 30 has a light transmittance of greater than about 90%, 95%, 97%, or 99%, with respect to a peak wavelength or a range of wavelengths of a light received or detected by the sensing area 210 of the sensing device 20. In some arrangements, the light transmissive member 30 is or includes a glass plate or a glass cover. In some arrangements, the light transmissive member 30 may be covered with an anti-reflective coating (not shown in drawings).

The bonding structure 40 may connect the light transmissive member 30 to the sensing device 20. The bonding structure 40 has an upper surface 401, a lower surface 402, and lateral surfaces 403 and 404. The lateral surfaces 403 and 404 may extend between the upper surface 401 and the lower surface 402. The lateral surface 403 may be opposite to the lateral surface 404. In some arrangements, the upper surface 401 is connected to the light transmissive member 30, and the lower surface 402 is connected to the sensing device 20. In some arrangements, the upper surface 401 contacts or directly contacts the light transmissive member 30, and the lower surface 402 contacts or directly contacts the sensing device 20. In some arrangements, the bonding structure 40 has a neck cross-sectional shape. In some arrangements, the lateral surface 403 includes a concave surface. In some arrangements, the lateral surface 403 has a non-uniform curvature. In some arrangements, the lateral surface 404 includes a concave surface. In some arrangements, the lateral surface 404 has a non-uniform curvature. In some arrangements, the lateral surfaces 403 and 404 have irregular surface structures or surface morphologies. In some arrangements, the lateral surfaces 403 and 404 have different surface morphologies.

Referring to FIGS. 1A-1B, in some arrangements, the bonding structure 40 has a non-uniform width. In some arrangements, the bonding structure 40 has a width from about 200 μm to about 400 μm. In some arrangements, the bonding structure 40 includes at least portions 40A and 40B on opposite sides of the sensing area 210 of the sensing device 20. In some arrangements, the portions 40A and 40B have different widths (e.g., cross-sectional widths). In some arrangements, referring to FIG. 1A, the upper surface 401 of the bonding structure 40 includes at least an upper surface 401a of the portion 40A and an upper surface 401b of the portion 40B. In some arrangements, referring to FIG. 1A, the lower surface 402 of the bonding structure 40 includes at least a lower surface 402a of the portion 40A and a lower surface 402b of the portion 40B.

In some arrangements, referring to FIGS. 1A-1B, the sensing device 20, the light transmissive member 30, and the bonding structure 40 define a cavity space S1. The cavity space S1 may be an enclosed space. In some arrangements, the sensing area 210 is exposed to the cavity space S1. In some arrangements, the bonding structure 40 is spaced apart from the sensing area 210. In some arrangements, the lateral surface 404 of the bonding structure 40 faces toward the cavity space S1. In some arrangements, the lateral surface 404 of the bonding structure 40 surrounds the cavity space S1. In some arrangements, a width WS1 of a top surface of the cavity space S1 is greater than a width WS2 of a bottom surface of the cavity space S1.

The encapsulant 50 may encapsulate the sensing device 20, the light transmissive member 30, the bonding structure 40, the conductive wires 62 and 63, and the adhesive layer 70. In some arrangements, the upper surface 301 of the light transmissive member 30 is exposed by an upper surface 501 of the encapsulant 50. In some arrangements, the lateral surfaces 303 and 304 of the light transmissive member 30 are partially exposed by the upper surface 501 of the encapsulant 50. In some arrangements, the light transmissive member 30 has two opposite lateral surface portions (e.g., a portion of the lateral surface 303 and a portion of the lateral surface 304) exposed by the encapsulant 50, and the exposed lateral surface portions have different exposed heights. In some arrangements, the exposed heights of the lateral surfaces 303 and 304 may be less than about 80 μm. According to some arrangements of the present disclosure, the exposed heights being less than about 80 μm may form a relatively smooth upper surface of the package structure 1, the edges of the light transmissive member 30 are relatively less protruded so as to prevent these edges from being damaged by impact. The encapsulant 50 may include an epoxy resin having fillers, a molding compound (e.g., an epoxy molding compound or other molding compound), polyimide, a phenolic compound or material, a material with a silicone dispersed therein, or a combination thereof.

The electrical contacts 80 may be electrically connected to the conductive layer 143 of the conductive structure 140 of the substrate 10. The electrical contacts 80 may provide electrical connections between the package structure 1 and external components (e.g. external circuits or circuit boards). In some embodiments, the electrical contacts 80 include controlled collapse chip connection (C4) bumps, a ball grid array (BGA), or a land grid array (LGA).

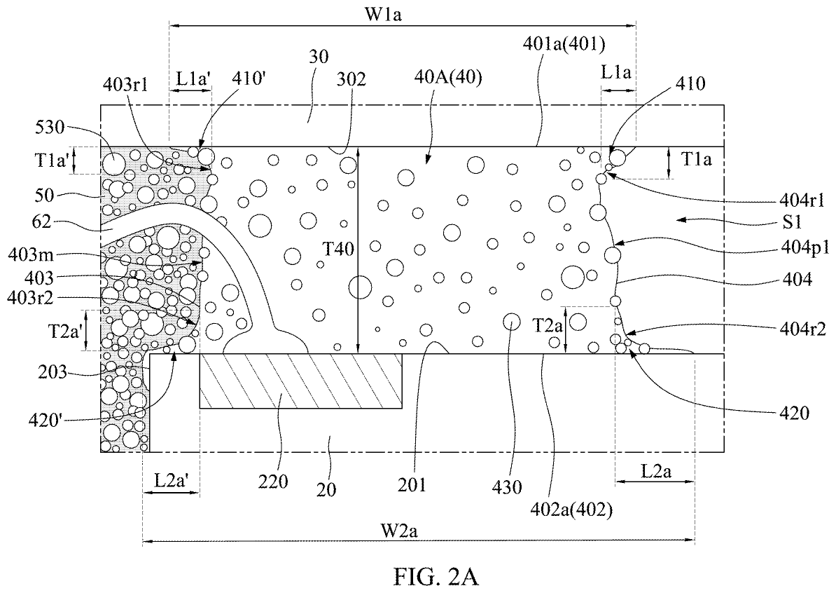

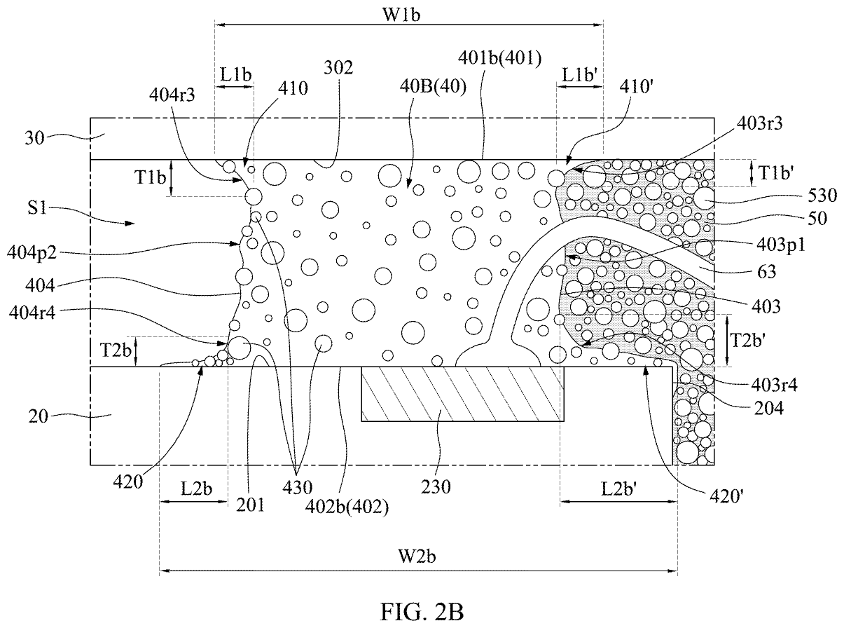

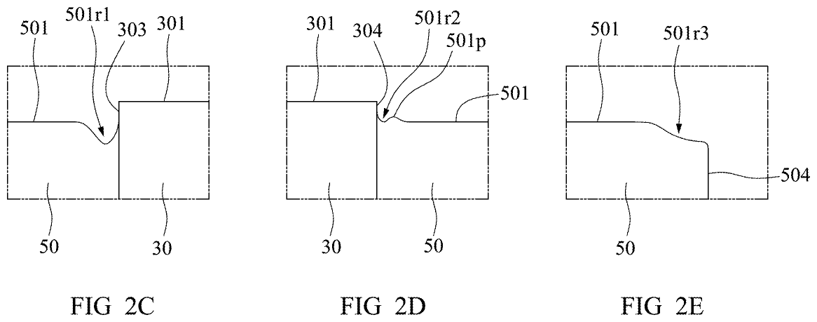

FIG. 2A is a cross-section of a portion of a package structure in accordance with some arrangements of the present disclosure. FIG. 2B is a cross-section of a portion of a package structure in accordance with some arrangements of the present disclosure. In some arrangements, FIG. 2A is a cross-section of a portion 2A of the package structure 1 in FIG. 1A, and FIG. 2B is a cross-section of a portion 2B of the package structure 1 in FIG. 1A.

In some arrangements, the bonding structure 40 includes a resin (e.g., an epoxy resin) and fillers 430 dispersed in the resin. In some arrangements, the bonding structure 40 has a modulus equal to or greater than about 1 GPa. In some arrangements, the bonding structure 40 has a modulus from about 1 GPa to about 20 GPa. According to some arrangements of the present disclosure, the bonding structure 40 has a relatively high modulus, such that is has sufficient structural strength to support the light transmissive member 30 (e.g., the glass plate), and the bonding structure 40 as well as the conductive wires 62 and 63 can be prevented from being damaged by mold flush which may occur in the process for forming the encapsulant 50.

In some arrangements, a width W1a of the upper surface 401a is less than a width W2a of the lower surface 402a of the bonding structure 40 (or the portion 40A). In some arrangements, a width W1b of the upper surface 401b is less than a width W2b of the lower surface 402b of the bonding structure 40 (or the portion 40B). In some arrangements, the bonding structure 40 (or the portions 40A and 40B) has a substantially uniform thickness T40.

In some arrangements, the bonding structure 40 includes protrusions 410, 410′, 420, and 420′. In some arrangements, the protrusions 410 and 410′ contact the light transmissive member 30, and the protrusions 420 and 420′ contact the sensing device 20. In some arrangements, referring to FIGS. 1B and 2A-2B, the protrusions 410 and 420 extend into or surround the cavity space S1.

Referring to FIG. 2A, in some arrangements, a thickness T1a of the protrusion 410 of the portion 40A and a thickness T2a of the protrusion 420 of the portion 40A decrease in a direction away from the bonding structure 40. In some arrangements, a length L1a of the protrusion 410 of the portion 40A is less than a length L2a of the protrusion 420 of the portion 40A. In some arrangements, a thickness T1a′ of the protrusion 410′ of the portion 40A and a thickness T2a′ of the protrusion 420′ of the portion 40A decrease in a direction toward an edge of the light transmissive member 30. In some arrangements, a thickness T1a′ of the protrusion 410′ of the portion 40A and a thickness T2a′ of the protrusion 420′ of the portion 40A decrease in a direction toward the encapsulant 50. In some arrangements, a length L1a′ of the protrusion 410′ of the portion 40A is less than a length L2a′ of the protrusion 420′ of the portion 40A. In some arrangements, the protrusion 420′ of the portion 40A contacts the upper surface 201 and a portion of a lateral surface 203 of the sensing device 20. The length of the protrusion may be defined by a distance between an edge of the protrusion and a bottom of a recess immediately adjacent to the protrusion. For example, the length L1a may be defined by a distance between an edge of the protrusion 410 and a bottom (e.g., a bottommost end or point) of the recess 404r1. The length of the protrusion may be defined by a distance between an edge of the protrusion and an inflection point of the lateral surface. For example, the length L1a may be defined by a distance between an edge of the protrusion 410 and an inflection point of the lateral surface 404. The inflection point may be the bottom (e.g., the bottommost end or point) of the recess 404r1.

Referring to FIG. 2B, in some arrangements, a thickness T1b of the protrusion 410 of the portion 40B and a thickness T2b of the protrusion 420 of the portion 40B decrease in a direction away from the bonding structure 40. In some arrangements, a length L1b of the protrusion 410 of the portion 40B is less than a length L2b of the protrusion 420 of the portion 40B. In some arrangements, a thickness T1b′ of the protrusion 410′ of the portion 40B and a thickness T2b′ of the protrusion 420′ of the portion 40B decrease in a direction toward an edge of the light transmissive member 30. In some arrangements, a thickness T1b′ of the protrusion 410′ of the portion 40B and a thickness T2b′ of the protrusion 420′ of the portion 40B decrease in a direction toward the encapsulant 50. In some arrangements, a length L1b′ of the protrusion 410′ of the portion 40B is less than a length L2b′ of the protrusion 420′ of the portion 40B. In some arrangements, the protrusion 420′ of the portion 40B contacts the upper surface 201 and a portion of a lateral surface 204 of the sensing device 20.

In some arrangements, the lateral surface 404 of the bonding structure 40 is exposed to the cavity space S1, and at least one of the fillers 430 is exposed by the lateral surface 404 of the bonding structure 40. In some arrangements, at least one of the fillers 430 is protruded beyond the lateral surface 404 of the bonding structure 40. A bonding material layer including fillers 430 may be used to form the bonding structure 40. In some arrangements, after the bonding material layer is heated, the volume of the bonding material layer may be reduced (the bonding material layer may shrink) due to vapor releasing out of the bonding material layer, and one or more fillers 430 originally dispersed within the bonding material layer may be exposed by or protruded out of the as-formed bonding structure 40. In some arrangements, at least one of the fillers 430 is partially protruded out of at least one of the protrusions 410, 410′, 420, and 420′. In some arrangements, at least one of the fillers 430 is exposed to the cavity space S1. In some arrangements, a number (or an amount or a distribution density) of the fillers 430 in the protrusion 410 is less than a number (or an amount or a distribution density) of the fillers 430 in the protrusion 420 in a cross-sectional view perspective. In some arrangements, a number (or an amount or a distribution density) of the fillers 430 in the protrusion 410′ is less than a number (or an amount or a distribution density) of the fillers 430 in the protrusion 420′ in a cross-sectional view perspective.

In some arrangements, the lateral surface 403 has one or more recesses (e.g., recesses 403r1, 403r2, 403r3, and 403r4) recessed toward an inner portion of the bonding structure 40. In some arrangements, the lateral surface 403 has one or more protrusions (e.g., a protrusion 403p1) connecting the recesses. In some arrangements, the recess 403r3 is between the protrusion 403p1 and the upper surface 401. In some arrangements, the lateral surface 404 has one or more recesses (e.g., recesses 404r1, 404r2, 404r3, and 404r4) recessed toward an inner portion of the bonding structure 40. In some arrangements, the lateral surface 404 has one or more protrusions (e.g., protrusions 404p1 and 404p2) connecting the recesses. In some arrangements, the recess 404r1 is between the protrusion 404p1 and the upper surface 401. In some arrangements, the recess 404r3 is between the protrusion 404p2 and the upper surface 401.

In some arrangements, the lateral surface 403 has an upper portion (e.g., the recesses 403r1 and 403r3) connected to the light transmissive member 30 and a lower portion (e.g., the recesses 403r2 and 403r4) connected to the sensing device 20. In some arrangements, the lateral surface 403 further has a middle portion (e.g., the surface portion 403m or the protrusion 403p1) between the upper portion and the lower portion. The upper portion and the lower portion of the lateral surface 403 may be recessed toward an inner portion of the bonding structure 40. A curvature of the upper portion may be greater than a curvature of the middle portion. A curvature of the lower portion may be greater than a curvature of the middle portion. In some arrangements, the curvature of the recess 403r1 and the curvature of the recess 403r2 are greater than a curvature of the surface portion 403m. In some arrangements, the curvature of the recess 403r3 and the curvature of the recess 403r4 are greater than a curvature of the protrusion 403p1.

In some arrangements, the lateral surface 404 has an upper portion (e.g., the recesses 404r1 and 404r3) connected to the light transmissive member 30 and a lower portion (e.g., the recesses 404r2 and 404r4) connected to the sensing device 20. In some arrangements, the lateral surface 404 further has a middle portion (e.g., the protrusions 404p1 and 404p2) between the upper portion and the lower portion. The upper portion and the lower portion of the lateral surface 404 may be recessed toward an inner portion of the bonding structure 40. A curvature of the upper portion may be greater than a curvature of the middle portion. A curvature of the lower portion may be greater than a curvature of the middle portion. In some arrangements, the curvature of the recess 404r1 and the curvature of the recess 404r2 are greater than a curvature of the protrusion 404p1. In some arrangements, the curvature of the recess 404r3 and the curvature of the recess 404r4 are greater than a curvature of the protrusion 404p1.

In some arrangements, the lateral surface 403 includes one or more concave portions (e.g., the recesses 403r1, 403r2, 403r3, and 403r4) and one or more convex portions (e.g., the protrusion 403p1), and the concave portions and the convex portions of the lateral surface 403 are recessed with respect to an edge portion of the upper surface 401 of the bonding structure 40 (e.g., an edge portion of the upper surface 401a of the portion 40A and/or an edge portion of the upper surface 401b of the portion 40B). In some arrangements, the lateral surface 404 includes one or more concave portions (e.g., the recesses 404r1, 404r2, 404r3, and 404r4) and one or more convex portions (e.g., the protrusions 404p1 and 404p2), and the concave portions and the convex portions of the lateral surface 404 are recessed with respect to an edge portion of the upper surface 401 of the bonding structure 40 (e.g., an edge portion of the upper surface 401a of the portion 40A and/or an edge portion of the upper surface 401b of the portion 40B). In some arrangements, the recesses 403r1, 404r1, 403r3, and 404r3 are recessed toward an edge portion of the upper surface 401 of the bonding structure 40. In some arrangements, the recesses 403r1 and 404r1 are recessed toward an edge portion of the upper surface 401a of the portion 40A. In some arrangements, the recesses 403r3 and 404r3 are recessed toward an edge portion of the upper surface 401b of the portion 40B. In some arrangements, the recesses 403r2, 404r2, 403r4, and 404r4 are recessed toward an edge portion of the lower surface 402 of the bonding structure 40. In some arrangements, the recesses 403r2 and 404r2 are recessed toward an edge portion of the lower surface 402a of the portion 40A. In some arrangements, the recesses 403r4 and 404r4 are recessed toward an edge portion of the lower surface 402b of the portion 40B. In some arrangements, a curvature of the recess 403r3 is greater than a curvature of the recess 403r4.

In some arrangements, the encapsulant 50 includes one or more portions filled in one or more of the concave portions of the lateral surface 403 of the bonding structure 40. In some arrangements, the concave portion of the lateral surface 403 has an irregular surface, and the portion of the encapsulant 50 is filled in and conformal to the irregular surface of the concave portion. In some arrangements, the encapsulant 50 includes fillers 530. In some arrangements, a density of fillers 530 in the encapsulant 50 is greater than a density of the fillers 430 in the bonding structure 40. In some arrangements, a density per unit area of the fillers 530 is greater than a density per unit area of the fillers 430 in a cross-sectional view perspective. In some arrangements, one or more of the fillers 430 are partially embedded in the bonding structure 40 and partially embedded in the encapsulant 50. In some arrangements, one or more of the fillers may be partially encapsulated by the bonding structure 40 and partially encapsulated by the encapsulant 50. In some arrangements, the fillers 530 are not extending into or embedded in the bonding structure 40. In some arrangements, the encapsulant 50 is formed after the bonding structure 40 is cured, one or more of the fillers 430 may partially protrude out of the bonding structure 40; therefore, the encapsulant 50 may cover or contact the protruded portions of the fillers 430, and the fillers 530 do not extend into the cured bonding structure 40.

FIG. 2C is a cross-section of a portion of a package structure in accordance with some arrangements of the present disclosure. FIG. 2D is a cross-section of a portion of a package structure in accordance with some arrangements of the present disclosure. FIG. 2E is a cross-section of a portion of a package structure in accordance with some arrangements of the present disclosure. In some arrangements, FIG. 2C is a cross-section of a portion 2C of the package structure 1 in FIG. 1A, FIG. 2D is a cross-section of a portion 2D of the package structure 1 in FIG. 1A, and FIG. 2E is a cross-section of a portion 2E of the package structure 1 in FIG. 1A.

The upper surface 501 of the encapsulant 50 may be lower than the upper surface 301 of the light transmissive member 30. In some arrangements, the upper surface 501 of the encapsulant 50 has one or more recesses (e.g., recesses 501r1, 501r2, and 501r3) and one or more protrusions (e.g., a protrusion 501p).

In some arrangements, referring to FIG. 2C, a portion of a lateral surface 303 of the light transmissive member 30 is exposed to the recess 501r1. In some arrangements, the recess 501r1 is recessed with respect to the planar portion of the upper surface 501. In some arrangements, referring to FIG. 2D, a portion of a lateral surface 304 of the light transmissive member 30 is exposed to the recess 501r2. In some arrangements, the recess 501r2 is recessed with respect to the protrusion 501p. In some arrangements, a bottom end of the recess 501r2 is substantially level to or higher than the planar portion of the upper surface 501. In some arrangements, a top end of the protrusion 501p is at an elevation between an elevation of the upper surface 301 of the light transmissive member 30 and an elevation of the bottom end of the recess 501r2 of the upper surface 501 of the encapsulant 50.

In some arrangements, the recess 501r3 is at an edge of the encapsulant 50. In some arrangements, the recess 501r3 is recessed from the upper surface 501 and the lateral surface 503 of the encapsulant 50.

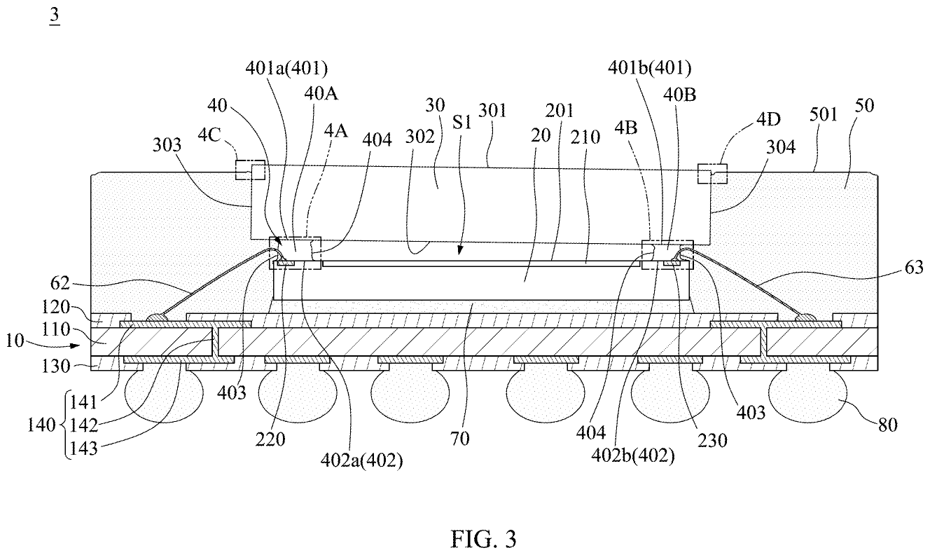

FIG. 3 is a cross-section of a package structure 3 in accordance with some arrangements of the present disclosure. The package structure 3 illustrated in FIG. 3 is similar to the package structure 1 illustrated in FIGS. 1A-1B, with differences therebetween as follows.

In some arrangements, the light transmissive member 30 is inclined with respect to the sensing device 20. In some arrangements, the lower surface 302 of the light transmissive member 30 is non-parallel to the upper surface 201 of the sensing device 20. In some arrangements, a maximum difference between elevations among the light transmissive member 30 may be about 30 μm or lower.

In some arrangements, the portion 40A and the portion 40B of the bonding structure 40 are spaced apart from each other. In some arrangements, the portion 40A and the portion 40B of the bonding structure 40 have different thicknesses. In some arrangements, the portion 40A has a thickness decreasing toward the portion 40B. In some arrangements, the portion 40B has a thickness decreasing toward a direction away from the portion 40A. In some arrangements, the lateral surfaces 303 and 304 of the light transmissive member 30 are partially exposed by the encapsulant 50 with different exposed heights. In some arrangements, the exposed heights of the lateral surfaces 303 and 304 may be less than about 80 μm.

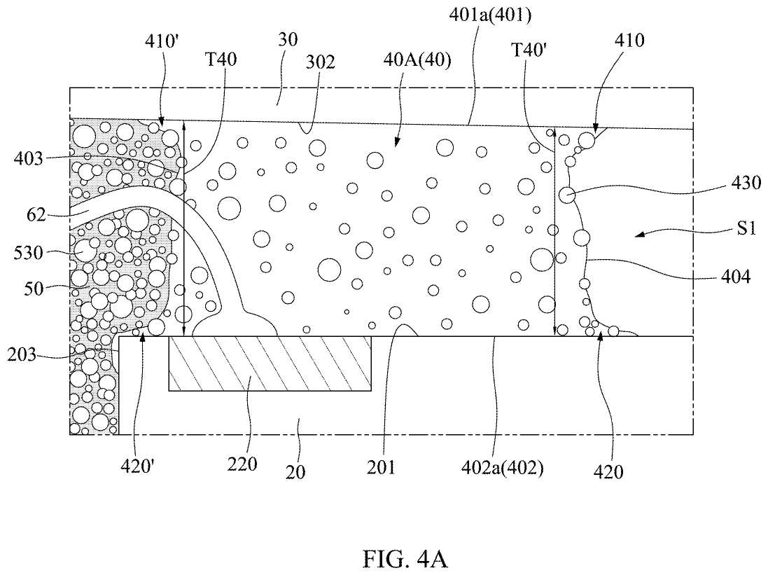

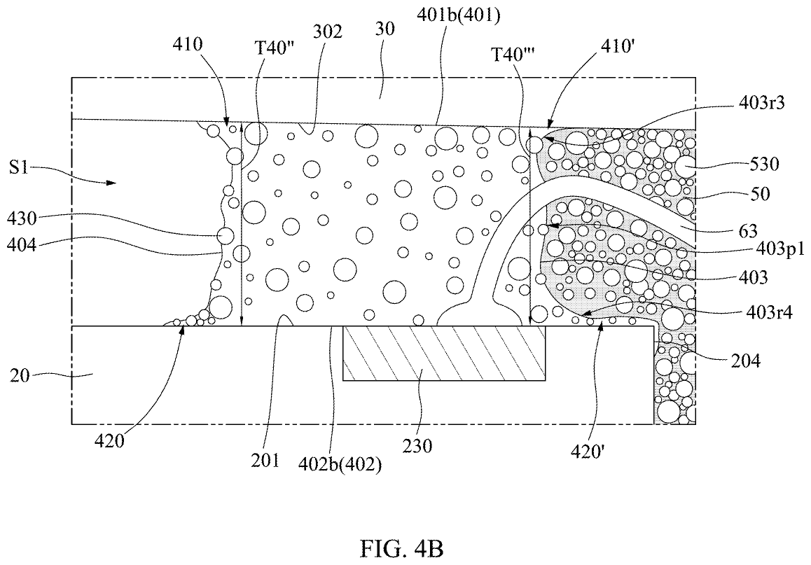

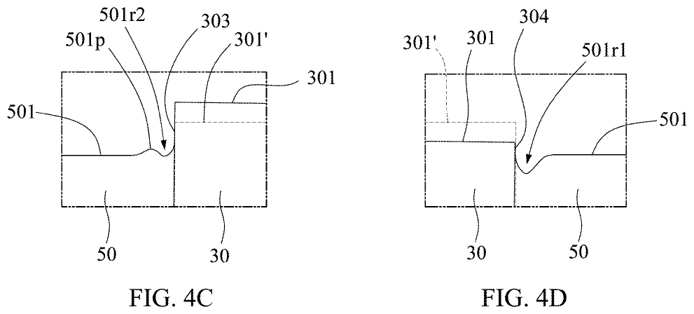

FIG. 4A is a cross-section of a portion of a package structure 3 in accordance with some arrangements of the present disclosure. FIG. 4B is a cross-section of a portion of a package structure 3 in accordance with some arrangements of the present disclosure. In some arrangements, FIG. 4A is a cross-section of a portion 4A of the package structure 3 in FIG. 3, and FIG. 4B is a cross-section of a portion 4B of the package structure 3 in FIG. 3.

Referring to FIG. 4A, in some arrangements, the portion 40A of the bonding structure 40 has a thickness decreasing toward the sensing area 210. In some arrangements, the portion 40A has a thickness T40 proximal to the encapsulant 50 and greater than a thickness T40′ distal from the encapsulant 50. In some arrangements, the upper surface 401a is inclined with respect to or non-parallel to the lower surface 402a. In some arrangements, the upper surfaces of the protrusion 410 and the protrusion 410′ of the portion 40A are at different elevations.

Referring to FIG. 4B, in some arrangements, the portion 40B of the bonding structure 40 has a thickness decreasing away from the sensing area 210. In some arrangements, the portion 40B has a thickness T40″ distal from the encapsulant 50 and greater than a thickness T40′″ proximal to the encapsulant 50. In some arrangements, the upper surface 401b is inclined with respect to or non-parallel to the lower surface 402b. In some arrangements, the upper surfaces of the protrusion 410 and the protrusion 410′ of the portion 40B are at different elevations. In some arrangements, the recess 403r3 is recessed toward an edge portion of the upper surface 401 of the bonding structure 40, and the recess 404r4 is recessed toward an edge portion of the lower surface 402 of the bonding structure 40. In some arrangements, a curvature of the recess 403r3 is greater than a curvature of the recess 403r4. In some arrangements, the protrusion 403p1 is defined by and between the recesses 403r3 and 403r4, and the curvature of the recess 403r3 is greater than a curvature of the protrusion 403p1.

FIG. 4C is a cross-section of a portion of a package structure 3 in accordance with some arrangements of the present disclosure. FIG. 4D is a cross-section of a portion of a package structure 3 in accordance with some arrangements of the present disclosure. In some arrangements, FIG. 4C is a cross-section of a portion 4C of the package structure 3 in FIG. 3, and FIG. 4D is a cross-section of a portion 4D of the package structure 3 in FIG. 3.

In some arrangements, referring to FIG. 4C, a portion of a lateral surface 303 of the light transmissive member 30 is exposed to the recess 501r2. In some arrangements, the recess 501r2 is recessed with respect to the protrusion 501p. In some arrangements, a bottom end of the recess 501r2 is substantially level to or higher than the planar portion of the upper surface 501. In some arrangements, a top end of the protrusion 501p is at an elevation between an elevation of the upper surface 301 of the light transmissive member 30 and an elevation of the bottom end of the recess 501r2 of the upper surface 501 of the encapsulant 50. In some arrangements, referring to FIG. 4D, a portion of a lateral surface 304 of the light transmissive member 30 is exposed to the recess 501r1. In some arrangements, the recess 501r1 is recessed with respect to the planar portion of the upper surface 501.

In some arrangements, the upper surface 301 of the light transmissive member 30 is inclined with respect to a virtual upper surface 301′ which is substantially parallel to the upper surface 201 of the sensing device 20. In some arrangements, the lateral surfaces 303 and 304 are partially exposed by the encapsulant 50, and an exposed height of the lateral surface 303 is greater than an exposed height of the lateral surface 304.

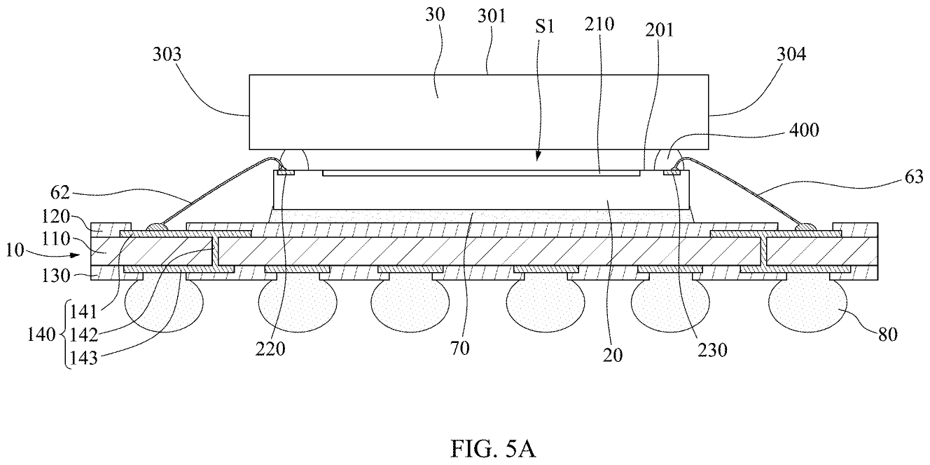

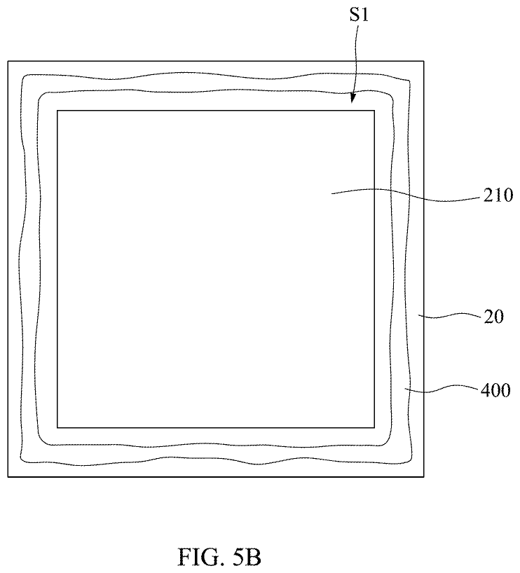

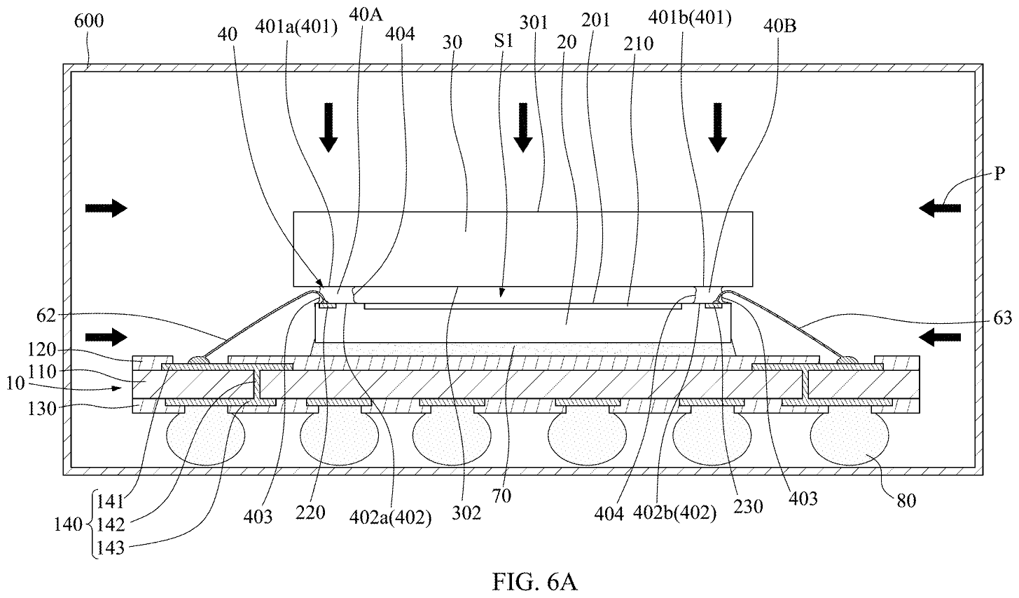

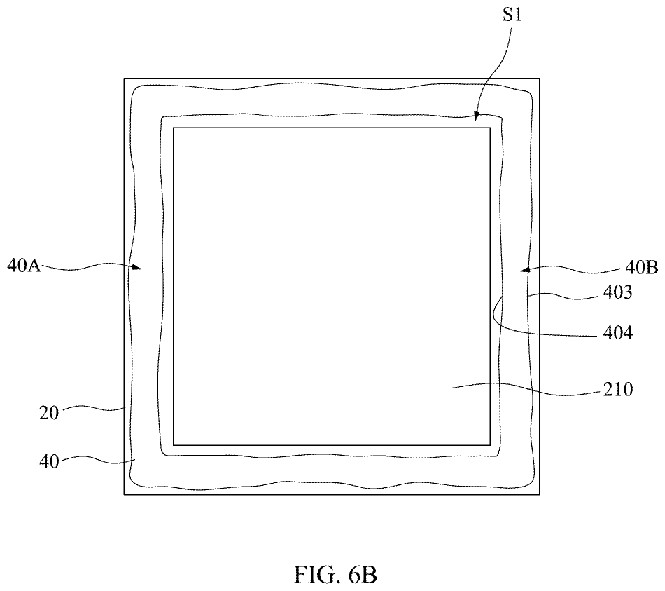

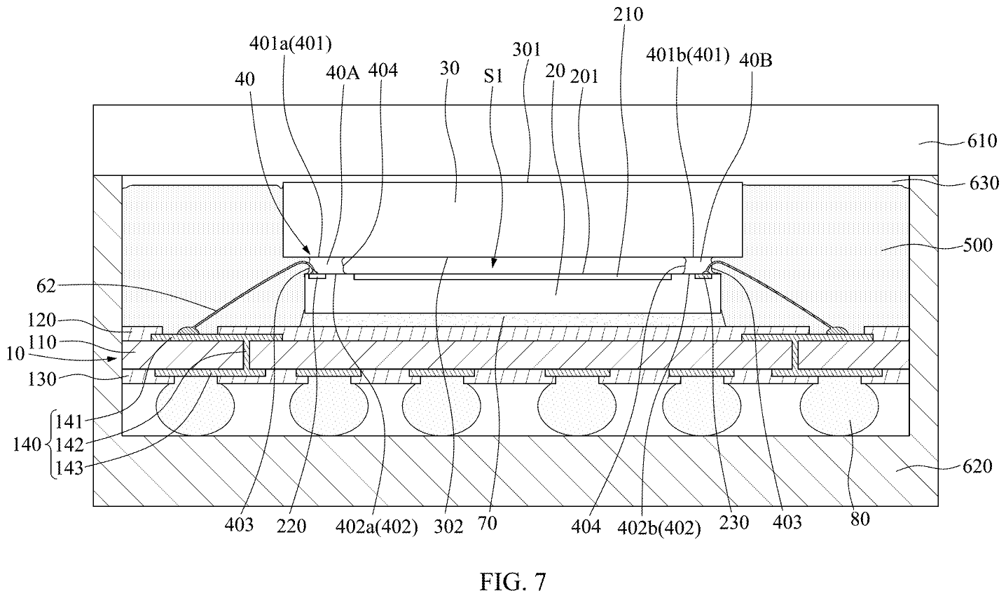

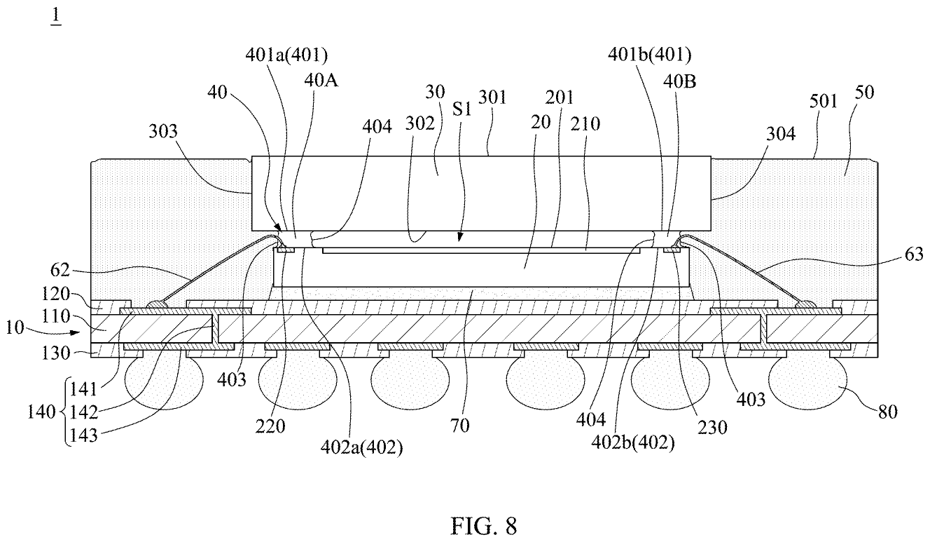

FIG. 5A, FIG. 5B, FIG. 6A, FIG. 6B, FIG. 7, and FIG. 8 illustrate various stages of an exemplary method for manufacturing a package structure 1 in accordance with some arrangements of the present disclosure.

Referring to FIGS. 5A and 5B, FIG. 5B is a top view of a portion of the structure illustrated in FIG. 5A. A substrate 10 may be provided, a sensing device 20 may be disposed over the substrate 10 and bonded to the substrate 10 through the conductive wires 62 and 63, and a light transmissive member 30 may be connected to or bonded to the sensing device 20. In some arrangements, a bonding material layer 400 is disposed on a peripheral region of an upper surface 201 of the sensing device 20, and the light transmissive member 30 is disposed on or attached to the bonding material layer 400. In some arrangements, the bonding material layer 400 may surround a sensing area 210 of the sensing device 20. In some arrangements, the bonding material layer 400 includes a resin material (e.g., an epoxy resin material) and fillers 430 dispersed in the resin material. The bonding material layer 400 may have a viscosity of about 100 Pa·s or higher. In some arrangements, the bonding material layer 400 may be disposed by dispensing, printing, or other suitable technique.

In some arrangements, the bonding material layer 400 may surround the sensing area 210 entirely, and the sensing device 20, the light transmissive member 30, and the bonding material layer 400 may form a cavity space S1 (or an enclosed space). In some arrangements, the bonding material layer 400 may have a semicircle cross-sectional shape with a top surface narrower than a bottom surface. In some other arrangements, the bonding material layer 400 may be disposed around the sensing device 20 without entirely surrounding the sensing area 210.

Referring to FIGS. 6A and 6B, FIG. 6B is a top view of a portion of the structure illustrated in FIG. 6A. The bonding material layer 400 may be cured to form a bonding structure 40 that attaches the light transmissive member 30 to the sensing device 20. The curing operation may include performing a heating operation. The heating operation may be performed under a temperature from about 120° C. to about 180° C. for about 30 minutes to about 2 hours, for example, at about 150° C. for about 1 hour. In some arrangements, the temperature may be raised from room temperature to about 150° C. in 30 minutes, maintained at 150° C. for about 1 hour, and then lowered to room temperature in 30 minutes.

In some arrangements, the curing operation may further include applying pressure P to the entire structure including the light transmissive member 30 and the bonding material layer 400 when heating. The pressure P may be applied from multiple directions to the upper surface 301 of the light transmissive member 30 and the outer lateral surface of the bonding material layer 400. For example, the bonding material layer 400 may be applied with the pressure P from the upper surface and the outer lateral surface. In addition, the gas (e.g., air) in the cavity space S1 (or the enclosed space) may expand by heating and thereby increasing the pressure within the cavity space S1. The increased pressure within the cavity space S1 (or the enclosed space) may be applied on the inner lateral surface of the bonding material layer 400 while the outer lateral surface of the bonding material layer 400 is subjected to the pressure P from outside of the cavity space S1 (or the enclosed space). Accordingly, a neck cross-sectional shape of the bonding structure 40 may be formed resulted from the pressure from the outer lateral surface and the inner lateral surface of the bonding material layer 400. For example, the pressure from the outer lateral surface and the inner lateral surface of the bonding material layer 400 may deform the bonding material layer 400 from a semicircle cross-sectional shape to form the bonding structure 40 having a neck cross-sectional shape. Moreover, the pressure within the cavity space S1 (or the enclosed space) may further push a portion of the bonding material layer 400 upwards to the lower surface 302 of the light transmissive member 30, so as to form the protrusions 410 and 410′ of the bonding structure 40.

Furthermore, the pressure P applied through the light transmissive member 30 toward the upper surface of the bonding material layer 400 may further slightly reduce the distance between the lower surface 302 of the light transmissive member 30 and the upper surface 201 of the sensing device 20, so as to form the bonding structure 40 having a thickness slightly smaller than the thickness of the bonding material layer 400. In addition, the as-formed bonding structure 40 may have a slightly increased width than that of the bonding material layer 400. In some arrangements, the pressure P may be about 0.3 kgf/cm² to about 0.7 kgf/cm² for about 30 minutes to about 2 hours, for example, about 0.5 kgf/cm² for about 1 hour. In some arrangements, the pressure P may be increased from 0.1 kgf/cm² to about 0.5 kgf/cm² in 30 minutes, maintained at 0.5 kgf/cm² for about 1 hour, and then lowered to 0.1 kgf/cm². The pressure P may be applied by disposing the entire structure in a pressure oven 600, and the pressure P within the pressure oven may be increased by introducing nitrogen gas.

According to some arrangements of the present disclosure, the bonding material layer 400 has a relatively high viscosity (e.g., 100 Pa·s or higher), such that the light transmissive member 30 can be attached to the sensing device 20 by the bonding material layer 400 in the curing operation. Therefore, the relative position between the light transmissive member 30 and the sensing device 20 can be relatively fixed.

Moreover, in some cases where curing the bonding material layer 400 is performed by heating without applying pressure, after the light transmissive member 30 is disposed on the bonding material layer 400, the pressure resulted from the weight of the light transmissive member 30 may cause the bonding material layer 400 to overflow and expand in its width. While the width of the bonding material layer 400 expand, the as-formed bonding structure 40 may have an undesired large width, which may over occupy a device area and even may exceed edges of the sensing device 20. In contrast, according to some arrangements of the present disclosure, the pressure P from the outer lateral surface of the bonding material layer 400 can prevented the bonding material layer 400 from overflowing and expanding in its width. Therefore, the as-formed bonding structure 40 may have a relatively satisfactory width (e.g., from about 200 μm to about 400 μm). In addition, the pressure P from the outer lateral surface of the bonding material layer 400 can further prevent the gas within the cavity space S1 (or the enclosed space) from rushing out of the cavity space S1 (or the enclosed space) to damage the bonding structure 40 and tilt the light transmissive member 30.

Referring to FIG. 7, an encapsulant material 500 may be disposed to encapsulate the sensing device 20, the light transmissive member 30, and the bonding structure 40. In some arrangements, the structure illustrated in FIG. 6 is disposed on a bottom mold 620, a top mold 610 is moved toward the bottom mold 620, and the encapsulant material 500 is filled into a space defined by the top mold 610 and the bottom mold 620 to encapsulate the sensing device 20, the light transmissive member 30, and the bonding structure 40. In some arrangements, the shape of the top mold 610 and the bottom mold 620 may be designed specifically for the entire structure to be encapsulated. In some arrangements, a release film 630 may be attached to the interior of the top mold 610. In some arrangements, the light transmissive member 30 may be partially extended or pressed into the release film 630 by the pressure or force from the top mold 610 when it is moved toward the bottom mold 620. Accordingly, the encapsulant material 500 may have some recesses that are conformal to the protruding portions of the release film 630. In some arrangements, portions of the release film 630 may deform and extend toward lateral surfaces 303 and 304 of the light transmissive member 30.

In some arrangements, the bonding structure 40 includes a resin (e.g., an epoxy resin) and fillers 430 dispersed in the resin. In some arrangements, the bonding structure 40 has a modulus equal to or greater than about 1 GPa. In some arrangements, the bonding structure 40 has a modulus from about 1 GPa to about 20 GPa.

According to some arrangements of the present disclosure, the bonding structure 40 has a relatively high modulus, such that is has a relatively strong structural strength. Therefore, the bonding structure 40 as well as the conductive wires 62 and 63 can be prevented from being damaged by mold flush which may occur in the process for forming the encapsulant 50, and the light transmissive member 30 can be maintained at a relatively stable position, such that inclination of the light transmissive member 30 can be mitigated or prevented (e.g., the maximum difference between elevations among the light transmissive member 30 may be reduced to about 30 μm or lower), and overflows of the encapsulant material 500 (e.g., the encapsulant material 500 overflowing to cover portions of the upper surface 301 of the light transmissive member 30) can be effectively prevented. With the aforesaid designs, the processing window for forming the encapsulant 50 can be enlarged, and thus the yield can be increased.

In addition, according to some arrangements of the present disclosure, the release film 630 covers the upper surface 301 of the light transmissive member 30 in the process for forming the encapsulant 50. Therefore, the encapsulant material 500 can be prevented from overflowing to the upper surface 301 of the light transmissive member 30, and thus the yield can be increased.

Referring to FIG. 8, the encapsulant material 500 illustrated in FIG. 7 may be cured to form an encapsulant 50, and the top mold 610, the bottom mold 620, and the release film 630 may be removed. As such, a package structure 1 is formed. In some arrangements, the release film 630 is attached to the top mold 610 and removed together with the top mold 610. In some arrangements, the encapsulant 50 may have some recesses (e.g., the recesses 501r1, 501r2, and 501r3 shown in FIGS. 2C-2E) resulted from the recesses of the encapsulant material 500.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to #10% of the second numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to +3°, less than or equal to ±2°, less than or equal to ±1°, less than or equal to ±0.5°, less than or equal to =0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate;
a sensing device over the substrate;
a light transmissive member over the sensing device; and
a bonding structure having an upper surface connected to the light transmissive member and a lower surface connected to the sensing device, wherein a width of the upper surface is less than a width of the lower surface of the bonding structure.

2. The package structure as claimed in claim 1, wherein the bonding structure comprises a first protrusion contacting the light transmissive member and a second protrusion contacting the sensing device, and a length of the first protrusion is less than a length of the second protrusion.

3. The package structure as claimed in claim 2, wherein a thickness of the first protrusion decreases in a direction toward an edge of the light transmissive member.

4. The package structure as claimed in claim 2, wherein the second protrusion contacts an upper surface and a portion of a lateral surface of the sensing device.

5. The package structure as claimed in claim 2, wherein the bonding structure comprises a plurality of fillers, and a number of the fillers in the first protrusion is lower than a number of the fillers in the second protrusion in a cross-sectional view perspective.

6. The package structure as claimed in claim 1, wherein the bonding structure further has a lateral surface extending between the upper surface and the lower surface, and the lateral surface has a protrusion and a recess between the protrusion and the upper surface.

7. The package structure as claimed in claim 1, wherein the bonding structure comprises a first portion and a second portion on opposite sides of a sensing area of the sensing device and having different widths.

8. The package structure as claimed in claim 7, wherein the first portion and the second portion of the bonding structure have different thicknesses.

9. A package structure, comprising:
a substrate;
a sensing device over the substrate;
a light transmissive member over the sensing device; and
a bonding structure having an upper surface contacting the light transmissive member, a lower surface contacting the sensing device, and a lateral surface including a first concave portion recessed toward an edge portion of the upper surface or an edge portion of the lower surface of the bonding structure.

10. The package structure as claimed in claim 9, further comprising an encapsulant encapsulating the sensing device and the bonding structure, wherein the encapsulant comprises a portion filled in the first concave portion of the lateral surface of the bonding structure.

11. The package structure as claimed in claim 10, wherein the light transmissive member has a lateral surface partially exposed by the encapsulant.

12. The package structure as claimed in claim 10, wherein the light transmissive member has two opposite lateral surface portions exposed by the encapsulant and having different exposed heights.

13. The package structure as claimed in claim 9, wherein the bonding structure comprises a first portion and a second portion spaced apart from the first portion, and the first portion of the bonding structure has a thickness decreasing toward the second portion.

14. The package structure as claimed in claim 9, wherein the first concave portion is recessed toward the edge portion of the upper surface, and the lateral surface of the bonding structure further includes a second concave portion recessed toward the edge portion of the lower surface, and a curvature of the first concave portion is greater than a curvature of the second concave portion.

15. The package structure as claimed in claim 14, wherein the lateral surface of the bonding structure further include a protrusion portion defined by the first concave portion and the second concave portion, and the curvature of the first concave portion is greater than a curvature of the protrusion portion.

16. A package structure, comprising:
a substrate;
a sensing device over the substrate;
a light transmissive member over the sensing device; and
a bonding structure connecting to the light transmissive member and the sensing device, wherein the sensing device, the light transmissive member, and the bonding structure collectively define a cavity space, and a width of a top surface of the cavity space is greater than a width of a bottom surface of the cavity space.

17. The package structure as claimed in claim 16, wherein the bonding structure has a surface exposed to the cavity space, and the bonding structure comprises a filler exposed by the surface of the bonding structure.

18. The package structure as claimed in claim 17, wherein the filler is protruded beyond the surface of the bonding structure.

19. The package structure as claimed in claim 16, further comprising an encapsulant and a plurality of fillers, wherein at least one of the fillers is partially encapsulated by the bonding structure and partially encapsulated by the encapsulant.

20. The package structure as claimed in claim 16, further comprising an encapsulant encapsulating the bonding structure, wherein the bonding structure comprises a plurality of first fillers, the encapsulant comprises a plurality of second fillers, and a density of the second fillers is greater than a density of the first fillers in a cross-sectional view perspective.
